(19) United States
(12) Patent Application Publication
(10) Pub. No.: US 2026/0082639 A1
(43) Pub. Date: Mar. 19, 2026

(54) SEMICONDUCTOR DEVICE AND MANUFACTURING METHOD OF SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Hidemoto TOMITA, Nisshin-shi (JP); Tomotaka ARIGA, Nisshin-shi (JP)

(21) Appl. No.: 19/271,015

(22) Filed: Jul. 16, 2025

(30) Foreign Application Priority Data
Sep. 19, 2024 (JP) 2024-162364

(51) Int. Cl. H10D 62/00; H10D 30/66; H10D 62/10; H10D 62/832

(52) U.S. Cl. CPC H10D 62/054; H10D 30/668; H10D 62/111; H10D 62/8325

(57) ABSTRACT

A manufacturing method of a semiconductor device includes forming an interposed film above a second conductivity type semiconductor layer, forming a shielding film containing metal above the interposed film, forming openings that penetrate through the shielding film, and forming first conductivity type columns and second conductivity type columns alternately and repeatedly arranged along at least one direction by implanting first conductivity type impurity ions into the second conductivity type semiconductor layer through the openings.

### CROSS REFERENCE TO RELATED APPLICATION

The present application claims the benefit of priority from Japanese Patent Application No. 2024-162364 filed on Sep. 19, 2024. The entire disclosure of the above application is incorporated herein by reference.

### TECHNICAL FIELD

The present disclosure relates to a semiconductor device and a manufacturing method of a semiconductor device.

### BACKGROUND

Semiconductor devices having a superjunction structure in which p-type columns and n-type columns are alternately and repeatedly arranged along at least one direction have been proposed. The semiconductor devices having the superjunction structure can achieve both low on-resistance and high breakdown voltage characteristics.

### SUMMARY

According to an aspect of the present disclosure, a manufacturing method of a semiconductor device having a superjunction structure in which first conductivity type columns and second conductivity type columns are alternately and repeatedly arranged along at least one direction is provided. The manufacturing method may include: forming an interposed film above a second conductivity type semiconductor layer; forming a shielding film containing metal above the interposed film; forming openings that penetrate through the shielding film; and forming the first conductivity type columns and the second conductivity type columns within the second conductivity type semiconductor layer by implanting first conductivity type impurity ions into the second conductivity type semiconductor layer through the openings.

### BRIEF DESCRIPTION OF DRAWINGS

Objects, features and advantages of the present disclosure will become apparent from the following detailed description made with reference to the accompanying drawings. In the drawings:

FIG. 1 is a diagram schematically showing a partial cross-sectional view of a semiconductor device according to an embodiment of the present disclosure;

FIG. 2 is a diagram schematically showing a partial cross-sectional view in a process in a first manufacturing method of the semiconductor device;

FIG. 3 is a diagram schematically showing a partial cross-sectional view in a process in the first manufacturing method of the semiconductor device;

FIG. 4 is a diagram schematically showing a partial cross-sectional view in a process in the first manufacturing method of the semiconductor device;

FIG. 5 is a diagram schematically showing a partial cross-sectional view in a process in the first manufacturing method of the semiconductor device;

FIG. 6 is a diagram schematically showing a partial cross-sectional view in a process in the first manufacturing method of the semiconductor device;

FIG. 7 is a diagram schematically showing a partial cross-sectional view in a process in the first manufacturing method of the semiconductor device;

FIG. 8 is a diagram schematically showing a partial cross-sectional view in a process in the first manufacturing method of the semiconductor device;

FIG. 9 is a diagram schematically showing a partial cross-sectional view in a process in the first manufacturing method of the semiconductor device;

FIG. 10 is a diagram schematically showing a partial cross-sectional view in a process in the first manufacturing method of the semiconductor device;

FIG. 11 is a diagram schematically showing a partial cross-sectional view in a process in a second manufacturing method of the semiconductor device; and

FIG. 12 is a diagram schematically showing a partial cross-sectional view in a process in a third manufacturing method of the semiconductor device.

### DETAILED DESCRIPTION

In order to improve characteristics of low on-resistance and high breakdown voltage in semiconductor devices having a superjunction structure, it is desirable to increase aspect ratios of both p-type columns and n-type columns. The superjunction structure may be formed by implanting impurity ions of one conductivity type (for example, a p-type impurity) into a semiconductor layer of the opposite conductivity type (for example, an n-type semiconductor layer). As a mask for ion implantation, a photoresist with openings corresponding to ion implantation regions may be used. In order to both shield the conductivity type impurity ions to be implanted and form high aspect ratio columns, it is necessary to increase a thickness of the photoresist and narrow a pitch of the openings formed in the photoresist. Thus, in the photoresist used to form high aspect ratio columns, the aspect ratio of the openings formed in the photoresist also becomes high. According to investigations by the present inventors, it has been found that there is a concern that the photoresist may incline when the aspect ratio of the openings formed in the photoresist increases.

According to first aspect of the present disclosure, a manufacturing method of a semiconductor device having a superjunction structure in which first conductivity type columns and second conductivity type columns are alternately and repeatedly arranged along at least one direction is provided. The manufacturing method includes: forming an interposed film above a second conductivity type semiconductor layer; after the forming the interposed film, forming a shielding film containing metal above the interposed film; after the forming the shielding film, forming openings that penetrate through the shielding film; and after the forming the openings, forming the first conductivity type columns and the second conductivity type columns within the second conductivity type semiconductor layer by implanting first conductivity type impurity ions into the second conductivity type semiconductor layer through the openings. The interposed film may be formed directly on the second conductivity type semiconductor layer, or the interposed film may be formed above the second conductivity type semiconductor layer via another layer. The shielding film may also be formed directly on the interposed film, or the shielding film may be formed above the interposed film via another layer. The shielding film containing metal has high shielding properties against the first conductivity type impurity. Therefore, a thickness of the shielding film can be reduced. As a result, an aspect ratio of the openings formed in the shielding film is reduced, thereby suppressing inclining of the shielding film.

According to a second aspect of the present disclosure, a semiconductor device has a superjunction structure in which first conductivity type columns and second conductivity type columns are alternately and repeatedly arranged along at least one direction. Each of the first conductivity type columns and the second conductivity type columns is made of silicon carbide. Furthermore, each of the first conductivity type columns and the second conductivity type columns has an aspect ratio of 8.5 or more. This semiconductor device has the superjunction structure including the columns with a high aspect ratio and can have a breakdown voltage of 850 V or more.

Hereinafter, a semiconductor device according to an embodiment of the present disclosure will be described with reference to the drawings. For the purpose of clarity of drawings, when components are repeatedly arranged, only one of the components may be denoted by a reference numeral.

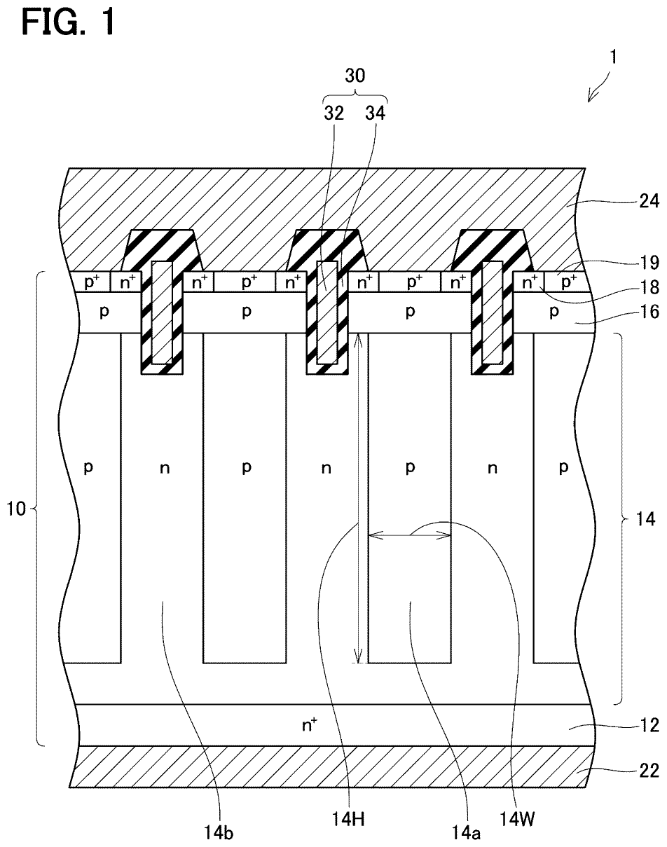

FIG. 1 is a diagram schematically showing a partial cross-sectional view of a semiconductor device 1. The semiconductor device 1 is a type of power semiconductor device called a metal oxide semiconductor field effect transistor (MOSFET), and includes a semiconductor layer 10, a drain electrode 22 covering a lower surface of the semiconductor layer 10, a source electrode 24 covering an upper surface of the semiconductor layer 10, and a plurality of trench gates 30 provided in an upper layer portion of the semiconductor layer 10.

The semiconductor layer 10 is made of a wide bandgap semiconductor. The semiconductor layer 10 is not particularly limited, and may be, for example, a 4H silicon carbide layer. The semiconductor layer 10 may be, instead of a silicon carbide layer, for example, a nitride semiconductor layer, a gallium oxide layer, a diamond layer, or the like. The semiconductor layer 10 includes a drain region 12 of n⁺-type, a drift region 14, a body region 16 of p-type, source regions 18 of n⁺-type, and body contact regions 19 of p⁺-type.

The drain region 12 is disposed in a lower portion of the semiconductor layer 10 and is provided at a position exposed on the lower surface of the semiconductor layer 10. The drain region 12 is in ohmic contact with the drain electrode 22 that covers the lower surface of the semiconductor layer 10. As will be described in a manufacturing method below, the drain region 12 is made of a silicon carbide substrate of n⁺-type and an epitaxial layer of n⁺-type grown on an upper surface of the silicon carbide substrate.

The drift region 14 is disposed between the drain region 12 and the body region 16, and includes a plurality of p-type columns 14a and a plurality of n-type columns 14b. The p-type columns 14a are an example of first conductivity type columns, and the n-type columns 14b are an example of second conductivity type columns. In the present embodiment, p-type is an example of a first conductivity type, and n-type is an example of a second conductivity type. The p-type columns 14a and n-type columns 14b are alternately and repeatedly arranged along at least one direction in a cross-section of the semiconductor layer 10, so as to form a superjunction structure. The p-type columns 14a and the n-type columns 14b are not particularly limited in their arrangement when viewed from a direction perpendicular to the upper surface of the semiconductor layer 10 (hereinafter referred to as “in plan view”), and, for example, may be arranged in a stripe pattern.

The p-type columns 14a have a height 14H measured from a lower surface to an upper surface, which is an interface with the body region 16, along a thickness direction of the semiconductor layer 10. The p-type columns 14a have a width 14W measured between side surfaces, which are interfaces with the n-type columns 14b, along a repetition direction of the superjunction structure. The height 14H of the p-type columns 14a is not particularly limited, and may be, for example, 3.4 μm or more. The width 14W of the p-type columns 14a is not particularly limited, and may be, for example, 0.4 μm or less. Accordingly, an aspect ratio of the p-type columns 14a may be 8.5 or more. The height 14H of the p-type columns 14a is not particularly limited, and may be, for example, 5.0 μm or less, or 4.5 μm or less. The width 14W of the p-type columns 14a is not particularly limited, and may be, for example, 0.2 μm or more. The height and width of the n-type columns 14b are the same as the p-type columns 14a. The aspect ratio of each of the p-type columns 14a and the n-type columns 14b is not particularly limited, and may be, for example, 25 or less, or 20 or less. The superjunction structure with such dimensions results in a breakdown voltage of the semiconductor device 1 of 850 V or more, as calculated from the breakdown electric field of silicon carbide.

The body region 16 is disposed above the drift region 14 and is positioned in the upper layer portion of the semiconductor layer 10. The body region 16 is disposed between the n-type columns 14b of the drift region 14 and the source regions 18, and separates the n-type columns 14b from the source regions 18. A concentration of p-type impurities in the body region 16 is adjusted according to a desired gate threshold voltage.

The source regions 18 are disposed above the body region 16, are positioned in the upper layer portion of the semiconductor layer 10, and are formed at locations exposed on the upper surface of the semiconductor layer 10. The source regions 18 are in contact with side surfaces of the trench gates 30. The source regions 18 are in ohmic contact with the source electrode 24, which covers the upper surface of the semiconductor layer 10.

The body contact regions 19 are disposed above the body region 16, are positioned in the upper layer portion of the semiconductor layer 10, and are formed at locations exposed on the upper surface of the semiconductor layer 10. The body contact regions 19 are in ohmic contact with the source electrode 24, which covers the upper surface of the semiconductor layer 10.

The trench gates 30 are filled in trenches formed in the upper layer portion of the semiconductor layer 10, penetrate through the source regions 18 and the body region 16, and reach the n-type columns 14b of the drift region 14. In this example, the trench gates 30 extend, in plan view of the semiconductor layer 10, along a longitudinal direction of the p-type columns 14a and the n-type columns 14b, that is, a direction perpendicular to the repetition direction of the superjunction structure. In another example, the trench gates 30 may extend, in plan view of the semiconductor layer 10, along the repetition direction of the p-type columns 14a and the n-type columns 14b. Each of the trench gates 30 includes a gate electrode 32 and a gate insulating layer 34. The gate electrodes 32 are formed of polysilicon containing impurities, and face the semiconductor layer 10 via the gate insulating layers 34. In particular, the gate electrodes 32 face, via the gate insulating layers 34, portions of the body region 16 that separate the n-type columns 14b of the drift region 14 and the source regions 18. The gate insulating layer 34 is made of silicon oxide and covers an inner wall of the trench.

Next, with reference to FIG. 1, the operation of the semiconductor device 1 will be described. When a potential of the gate electrodes 32 of the trench gates 30 is more positive than a potential of the source electrode 24 and is controlled to be higher than a threshold value in a state where a potential of the drain electrode 22 is more positive than the potential of the source electrode 24, the semiconductor device 1 is turned on. At this time, inversion layers are formed in the portions of the body region 16 that separate the n-type columns 14b of the drift region 14 and the source regions 18. Electrons supplied from the source regions 18 reach the n-type columns 14b of the drift region 14 via channels of the inversion layers. The electrons that have reached the n-type columns 14b flow into the drain region 12 via the n-type columns 14b. Since the n-type columns 14b have a high concentration of n-type impurities, the semiconductor device 1 can exhibit characteristics of low on-resistance.

When the potential of the gate electrodes 32 of the trench gates 30 is controlled to be the same as the potential of the source electrode 24, the channels of the inversion layers disappear, and the semiconductor device 1 is turned off. The p-type columns 14a and n-type columns 14b that constitute the superjunction structure are substantially fully depleted, and a wide region of the drift region 14 is depleted. In addition, since the drift region 14 has the superjunction structure, the electric field distribution in the drift region 14 is leveled in the depth direction. Therefore, the drift region 14 can withstand a large potential difference, so the semiconductor device 1 can have high breakdown voltage characteristics.

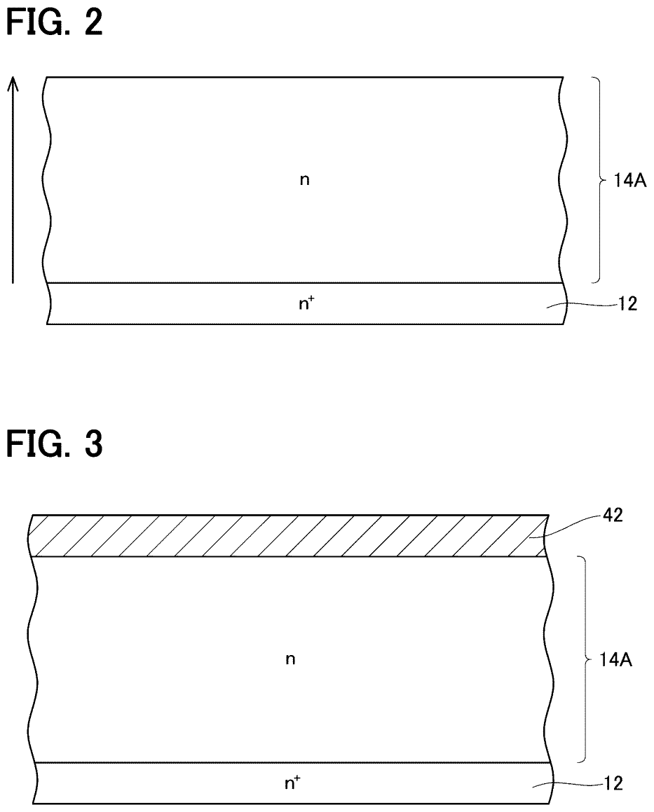

Next, with reference to FIGS. 2 to 10, processes of forming the superjunction structure in a first manufacturing method of the semiconductor device 1 will be described. As detailed below, the superjunction structure is formed by vertically connecting p-type columns and n-type columns, each of which is formed in a lower epitaxial layer and an upper epitaxial layer, respectively. The other processes for manufacturing the semiconductor device 1 can utilize known manufacturing techniques as necessary.

First, as shown in FIG. 2, the drain region 12 is prepared. The drain region 12 is formed by growing an epitaxial layer of n⁺-type on a surface of a silicon carbide substrate of n⁺-type. Next, using epitaxial growth techniques, a lower epitaxial layer 14A of n-type is grown from a surface of the drain region 12. A thickness of the lower epitaxial layer 14A is not particularly limited, and may be, for example, 1.8 μm. It should be noted that the lower epitaxial layer 14A constitutes at least a part of the semiconductor layer 10, and may also be referred to as a semiconductor layer of n-type. The lower epitaxial layer 14A is an example of a second conductivity type semiconductor layer.

Next, as shown in FIG. 3, for example, using vapor deposition techniques such as chemical vapor deposition (CVD), an interposed film 42 is formed above the lower epitaxial layer 14A. The interposed film 42 is not particularly limited, and may be, for example, an oxide film such as silicon oxide. A thickness of the interposed film 42 is not particularly limited, and may be, for example, 50 nm. The interposed film 42 formed above the lower epitaxial layer 14A is an example of a first interposed film.

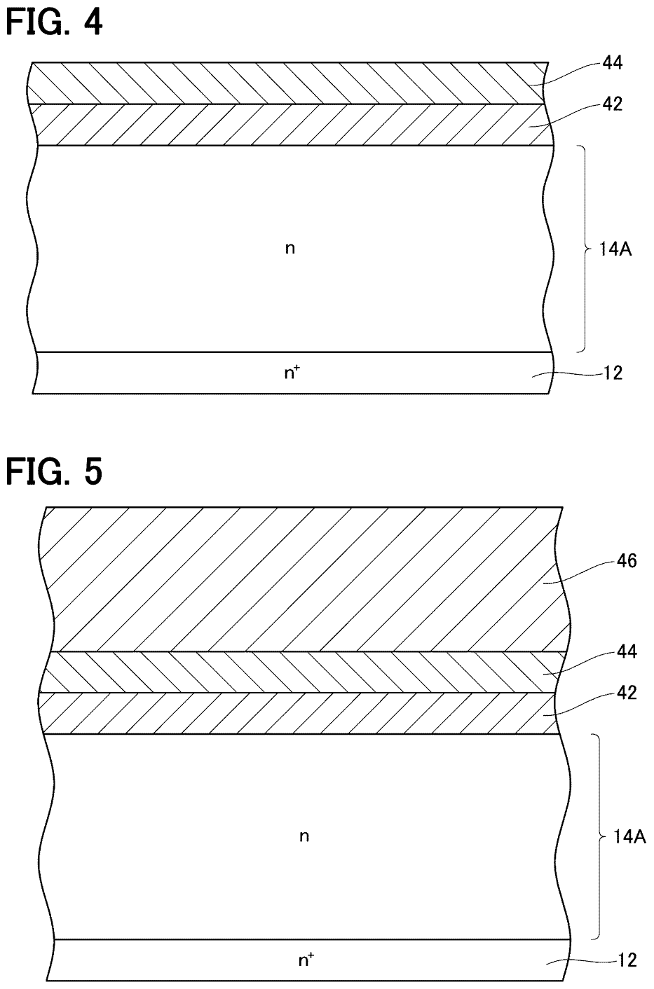

Next, as shown in FIG. 4, for example, using vapor deposition techniques such as sputtering, a bonding film 44 is formed above the interposed film 42. The bonding film 44 is disposed between a shielding film 46, which will be described later, and the interposed film 42, and improves the adhesion between the shielding film 46 and the interposed film 42. The bonding film 44 may be formed of a single film containing metal, or may be formed by laminating a plurality of films containing metal. The metal contained in the bonding film 44 is a metal that forms an oxide having a higher absolute value of Gibbs free energy of formation (|ΔG|) than the oxide of the interposed film 42 (in this example, silicon oxide), that is, a metal that is more easily oxidized than the interposed film 42. For example, the metal contained in the bonding film 44 may include at least one selected from a group consisting of Sn, Ge, In, Cs, Zn, Mn, Ga, Cr, Nb, Na, Ta, B, V, Ti, Ba, Zr, Al, Hf, Li, Sr, La, Mg, Be, Ca, and Y. The bonding film 44 is not particularly limited, and may be a single film of one of these metals (for example, a Ti film or a Ta film), or a nitride film of one of these metals (for example, a TiN film or a TaN film). A thickness of the bonding film 44 is not particularly limited, and may be, for example, 100 nm.

Next, as shown in FIG. 5, the shielding film 46 is formed above the bonding film 44 by using deposition techniques such as sputtering, CVD, or atomic layer deposition (ALD), for example. The shielding film 46 is a film containing metal. The shielding film 46 is not particularly limited, and may be, for example, a single film of tungsten. A thickness of the shielding film 46 is not particularly limited, and may be, for example, 1.1 μm. The shielding film 46 is an example of a first shielding film.

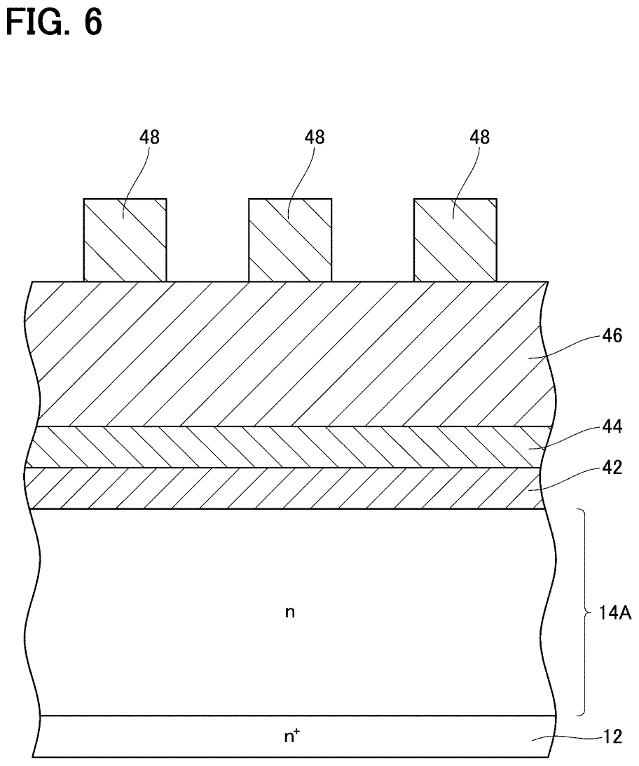

Next, as shown in FIG. 6, a mask 48 is patterned above the shielding film 46 using photolithography techniques. The mask 48 is opened in correspondence with formation regions of the p-type columns 14a (see FIG. 1). The mask 48 is not particularly limited, and may be, for example, an oxide film such as silicon oxide.

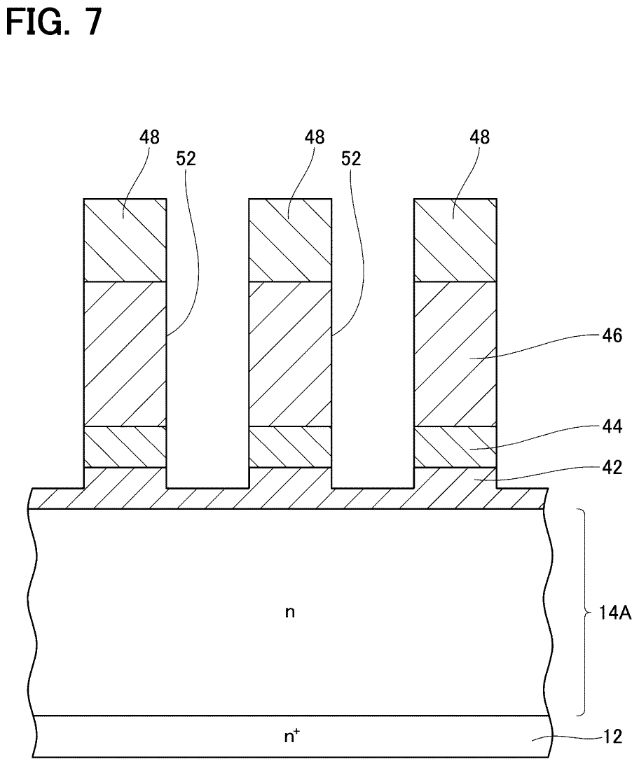

Next, as shown in FIG. 7, openings 52 penetrating through the shielding film 46 and exposed through the openings of the mask 48 are formed using etching techniques such as reactive ion etching (RIE). The openings 52 are an example of first openings. In this example, the openings 52 penetrate through not only the shielding film 46 but also the bonding film 44, but does not penetrate through the interposed film 42. Bottom surfaces of the openings 52 are located within the interposed film 42, with portions of the interposed film 42 left above the lower epitaxial layer 14A. In another example, the openings 52 may penetrate through the interposed film 42.

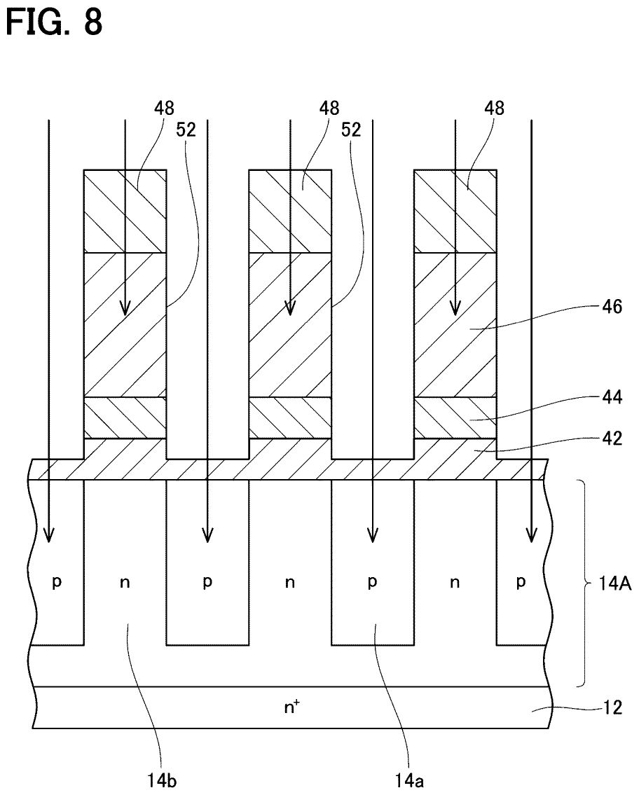

Next, as shown in FIG. 8, using ion implantation techniques, a p-type impurity is ion-implanted into the lower epitaxial layer 14A through the openings 52. The p-type impurity is not particularly limited, and may be, for example, aluminum. Regions of the lower epitaxial layer 14A into which the p-type impurity has been introduced become the p-type columns 14a, and regions sandwiched between the p-type columns 14a become the n-type columns 14b. As a result, a structure in which the p-type columns 14a and the n-type columns 14b are alternately and repeatedly arranged along one direction is formed within the lower epitaxial layer 14A.

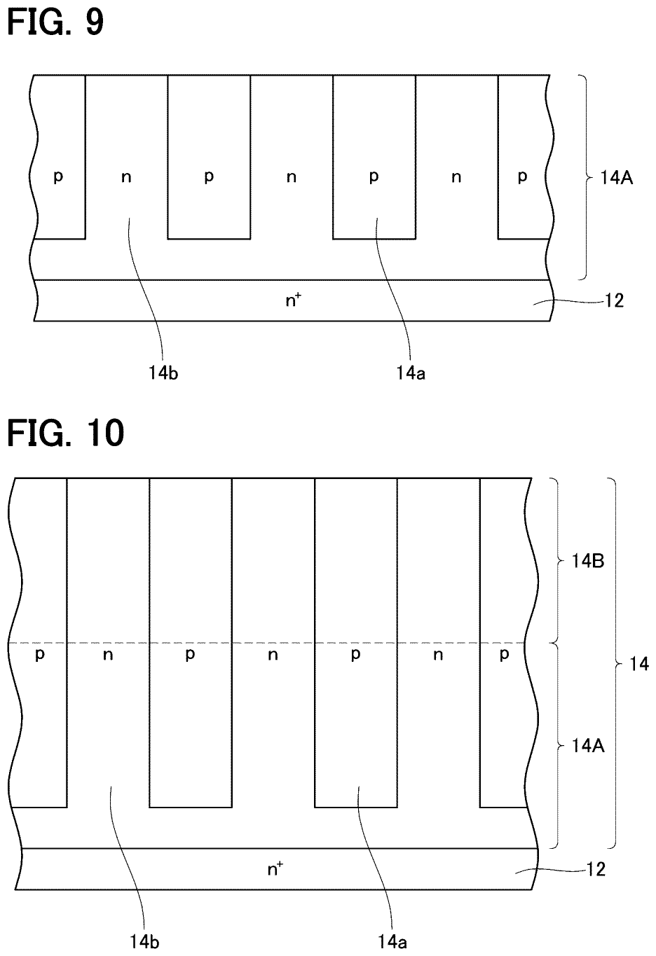

Next, as shown in FIG. 9, the interposed film 42, the bonding film 44, the shielding film 46, and the mask 48 formed above the lower epitaxial layer 14A are removed using a lift-off method. Specifically, by etching the interposed film 42 using an etching solution (for example, hydrofluoric acid) that has a higher etching rate for the interposed film 42 than for the shielding film 46, the bonding film 44, the shielding film 46, and the mask 48 laminated above the interposed film 42 are removed.

Next, as shown in FIG. 10, after an upper epitaxial layer 14B is grown above the lower epitaxial layer 14A using epitaxial growth techniques, a structure in which the p-type columns 14a and the n-type columns 14b are alternately and repeatedly arranged along one direction is formed within the upper epitaxial layer 14B. The upper epitaxial layer 14B is an example of a second conductivity type epitaxial layer. The upper epitaxial layer 14B is formed by re-executing each of the processes described with reference to FIGS. 2 to 8. Specifically, a second interposed film is formed above the upper epitaxial layer 14B, a second shielding film is formed above the second interposed film, second openings are formed to penetrate through the second shielding film, and the p-type columns 14a and the n-type columns 14b are formed within the upper epitaxial layer 14B by implanting p-type impurity ions into the upper epitaxial layer 14B through the second openings. Accordingly, the p-type columns 14a and the n-type columns 14b formed in the upper epitaxial layer 14B and the p-type columns 14a and the n-type columns 14b formed in the lower epitaxial layer 14A are vertically connected, respectively, so as to form the superjunction structure.

Thereafter, the body region 16 containing the p-type impurity is formed above the upper epitaxial layer 14B using epitaxial growth techniques, the source regions 18 and the body contact regions 19 are formed in predetermined regions within the body region 16 using ion implantation techniques, and various electrode structures (the trench gate 30, the drain electrode 22, and the source electrode 24) are formed. Accordingly, the semiconductor device 1 is completed.

In the above-described manufacturing method, the shielding film 46 containing metal is used as a mask for ion implantation. The shielding film 46 containing metal has a high shielding property against the p-type impurity (aluminum in this example). Therefore, even if the thickness of the shielding film 46 is thin, the shielding film 46 can sufficiently shield the p-type impurity and prevent p-type impurity from being implanted into non-ion-implanted regions of the epitaxial layers 14A and 14B. Since the thickness of the shielding film 46 is thin, the aspect ratio of the openings 52 formed in the shielding film 46 becomes low. As a result, the occurrence of situations such as the partition walls between the openings 52 of the shielding film 46 inclining can be suppressed.

In the above-described manufacturing method, the interposed film 42 is provided between the epitaxial layers 14A and 14B and the shielding film 46. The presence of the interposed film 42 suppresses metal contamination caused by the metal contained in the shielding film 46 (tungsten in this example) penetrating into the epitaxial layers 14A and 14B. For example, if the metal contained in the shielding film 46 remains between the lower epitaxial layer 14A and the upper epitaxial layer 14B, there is concern that the charge balance of the superjunction structure may be disrupted, resulting in a reduction in the breakdown voltage of the semiconductor device 1. Therefore, the above-described manufacturing method is particularly useful when forming a superjunction structure in two steps.

In the above-described manufacturing method, when the openings 52 are formed in the shielding film 46, the interposed film 42 is left above the epitaxial layers 14A and 14B. According to this method, the interposed film 42 can function as a protective film when forming the openings 52 in the shielding film 46. Therefore, when forming the openings 52 in the shielding film 46, damage to upper surfaces of the epitaxial layers 14A and 14B can be suppressed. In addition, the interposed film 42 left above the epitaxial layers 14A and 14B can function as a through-film during the ion implantation of the p-type impurity. Therefore, damage to the upper surfaces of the epitaxial layers 14A and 14B during ion implantation can also be suppressed.

In the above-described manufacturing method, since the shielding film 46 is formed above the interposed film 42, the shielding film 46 can be easily removed by etching the interposed film 42. In order to utilize the lift-off method, it is desirable that the adhesion between the interposed film 42 and the shielding film 46 be high. In the above-described manufacturing method, the bonding film 44 is provided between the interposed film 42 and the shielding film 46, thereby enhancing the adhesion between the interposed film 42 and the shielding film 46. In the case where the bonding film 44 is a single metal film (for example, a Ti film or a Ta film), oxygen is extracted from the oxide film of the interposed film 42 and the bonding film 44 is oxidized, resulting in mixing at the interface between the interposed film 42 and the bonding film 44, and thereby high adhesion is exhibited between the interposed film 42 and the bonding film 44. On the other hand, if the oxidation of the bonding film 44 progresses and an oxide film is also formed on an upper surface of the bonding film 44, that is, at an interface between the bonding film 44 and the shielding film 46, the adhesion between the bonding film 44 and the shielding film 46 may decrease. Therefore, the bonding film 44 may be a metal nitride film (for example, a TiN film or a TaN film). The formation of an oxide film between the bonding film 44 and the shielding film 46 is suppressed, and high adhesion is exhibited between the bonding film 44 and the shielding film 46.

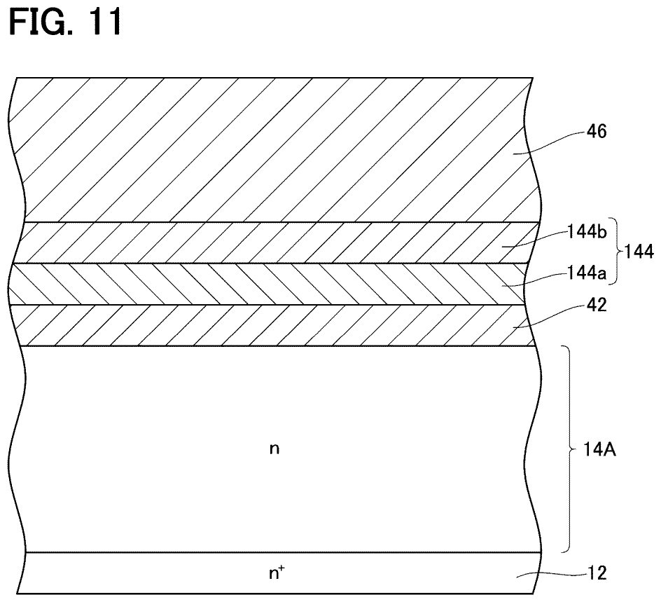

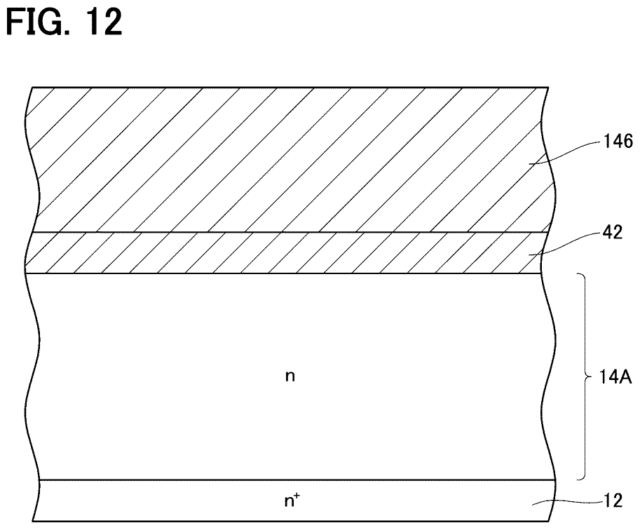

FIG. 11 is a diagram schematically showing a partial cross-sectional view in a process in a second manufacturing method of the semiconductor device 1 and corresponds to FIG. 5 in the first manufacturing method. In the second manufacturing method, a bonding film 144 includes a first bonding film 144a and a second bonding film 144b. The first bonding film 144a is adjacent to the interposed film 42, is provided between the interposed film 42 and the second bonding film 144b, and is in contact with the interposed film 42. The second bonding film 144b is adjacent to the shielding film 46, is provided between the first bonding film 144a and the shielding film 46, and is in contact with the shielding film 46. The first bonding film 144a is a single metal film (for example, a Ti film or a Ta film), and the second bonding film 144b is a metal nitride film (for example, a TiN film or a TaN film). The first bonding film 144a, which is a single metal film, exhibits high adhesion to the interposed film 42 due to the mixing effect, and the second bonding film 144b, which is a metal nitride film, exhibits high adhesion to the shielding film 46 by suppressing the formation of an oxide film. In this way, when the bonding film 144 is configured as a laminate of the single metal film and the metal nitride film, the adhesion between the interposed film 42 and the shielding film 46 is improved.

FIG. 12 is a diagram schematically showing a partial cross-sectional view in a process in a third manufacturing method of the semiconductor device 1 and corresponds to FIG. 5 in the first manufacturing method and FIG. 11 in the second manufacturing method. In the third manufacturing method, the bonding films 44 and 144 are not provided, and a shielding film 146 is in contact with the interposed film 42. The shielding film 146 is made of tungsten silicide (WSi₂). Tungsten silicide exhibits good adhesion to an oxide film. Therefore, when the material of the shielding film 146 is tungsten silicide, the bonding films 44 and 144 become unnecessary. Therefore, this manufacturing method enables the semiconductor device 1 to be produced at a low manufacturing cost. It should be noted that although the shielding film 146 made of tungsten silicide provides slightly less shielding property against p-type impurities than the shielding film 46 made of tungsten, it still has sufficient shielding properties, for example, compared to resist. In addition, the shielding film 146 made of tungsten silicide has an advantage that its edge roughness is finished more sharply compared to the shielding film 46 made of tungsten.

Although specific examples of the present disclosure have been described in detail above, these are merely examples and do not limit the scope of claims. The techniques described in the claims include various modifications and modifications of the specific examples illustrated above. In addition, the technical elements described in the present specification or the drawings exhibit technical usefulness alone or in various combinations, and are not limited to the combinations described in the claims at the time of filing. In addition, the techniques illustrated in the present specification or the drawings can achieve multiple purposes at the same time, and achieving one of the purposes itself has technical usefulness.

What is claimed is:

1. A manufacturing method of a semiconductor device having a superjunction structure in which first conductivity type columns and second conductivity type columns are alternately and repeatedly arranged along at least one direction, the manufacturing method comprising:
forming an interposed film above a second conductivity type semiconductor layer;
after the forming the interposed film, forming a shielding film containing metal above the interposed film;
after the forming the shielding film, forming openings that penetrate through the shielding film; and
after the forming the openings, forming the first conductivity type columns and the second conductivity type columns within the second conductivity type semiconductor layer by implanting first conductivity type impurity ions into the second conductivity type semiconductor layer through the openings.

2. The manufacturing method according to claim 1, further comprising
after the forming the first conductivity type columns and the second conductivity type columns, lifting off the shielding film by etching the interposed film.

3. The manufacturing method according to claim 2, wherein the interposed film is a first interposed film, the shielding film is a first shielding film, and the openings are first openings, the manufacturing method further comprising:
after the lifting off the shielding film, forming a second conductivity type epitaxial layer above the second conductivity type semiconductor layer;
after the forming the second conductivity type epitaxial layer, forming a second interposed film above the second conductivity type epitaxial layer;
after the forming the second interposed film, forming a second shielding film above the second interposed film;
after the forming the second interposed film, forming second openings that penetrate through the second shielding film; and
after the forming the second openings, forming the first conductivity type columns and the second conductivity type columns within the second conductivity type epitaxial layer by implanting first conductivity type impurity ions into the second conductivity type epitaxial layer through the second openings so as to form the superjunction structure in which the first conductivity type columns and the second conductivity type columns formed within the second conductivity type epitaxial layer are connected with the first conductivity type columns and the second conductivity type columns formed within the second conductivity type semiconductor layer, respectively.

4. The manufacturing method according to claim 1, wherein
the second conductivity type semiconductor layer is made of silicon carbide, and
each of the first conductivity type columns and the second conductivity type columns has an aspect ratio of 8.5 or more.

5. The manufacturing method according to claim 1, wherein
the metal contained in the shielding film includes at least tungsten.

6. The manufacturing method according to claim 1, wherein
the interposed film is an oxide film.

7. The manufacturing method according to claim 6, further comprising
forming a bonding film between the forming the interposed film and the forming the shielding film, wherein
the shielding film is a single metal film of tungsten, and
the bonding film contains at least one selected from a group consisting of Sn, Ge, In, Cs, Zn, Mn, Ga, Cr, Nb, Na, Ta, B, V, Ti, Ba, Zr, Al, Hf, Li, Sr, La, Mg, Be, Ca, and Y.

8. The manufacturing method according to claim 7, wherein
the bonding film is a TaN film or a TiN film.

9. The manufacturing method according to claim 7, wherein
the bonding film includes a first bonding film adjacent to the interposed film and a second bonding film adjacent to the shielding film,
the first bonding film is a single metal film, and
the second bonding film is a metal nitride film.

10. The manufacturing method according to claim 9, wherein
the first bonding film is a Ti film or a Ta film, and
the second bonding film is a TiN film or a TaN film.

11. The manufacturing method according to claim 5, wherein
the shielding film is made of tungsten silicide.

12. The manufacturing method according to claim 11, wherein
the shielding film is in contact with the interposed film.

13. The manufacturing method according to claim 1, wherein
the forming the openings includes leaving the interposed film above the second conductivity type semiconductor layer, and
the forming the first conductivity type columns and the second conductivity type columns includes implanting the first conductivity type impurity ions through the interposed film that has been left.

14. The manufacturing method according to claim 1, wherein
the second conductivity type semiconductor layer is made of a wide bandgap semiconductor.

15. A semiconductor device comprising:
a superjunction structure is which first conductivity type columns and second conductivity type columns are alternately and repeatedly arranged along at least one direction, wherein
each of the first conductivity type columns and the second conductivity type columns is made of silicon carbide, and
each of the first conductivity type columns and the second conductivity type columns has an aspect ratio of 8.5 or more.

16. The semiconductor device according to claim 15, wherein
each of the first conductivity type columns has a width of 0.4 μm or less.

17. The semiconductor device according to claim 15, wherein
each of the first conductivity type columns has a height of 3.4 μm or more.
